(19) United States
(12) Patent Application Publication
(10) Pub. No.: US 2025/0006877 A1
(43) Pub. Date: Jan. 2, 2025

(54) LIGHT-EMITTING DEVICE

(71) Applicant: NICHIA CORPORATION, Tokushima (JP)

(72) Inventor: Kenta MITSUYAMA, Tokushima-shi (JP)

(21) Appl. No.: 18/753,719

(22) Filed: Jun. 25, 2024

(30) Foreign Application Priority Data
Jun. 30, 2023 (JP) 2023-107632

(51) Int. Cl. H01L 33/60

(52) U.S. Cl. CPC H01L 33/60

(57) ABSTRACT

A light-emitting device includes a support; a first light-emitting element and a second light-emitting element aligned in a first direction and located on the support; a light-transmissive member including a first lens portion overlapping the first light-emitting element in a top view, a second lens portion overlapping the second light-emitting element in a top view, and a first connecting portion connecting the first lens portion and the second lens portion; and a reflective member overlapping the first connecting portion in top view.

### CROSS REFERENCE TO RELATED APPLICATION

This application claims priority to Japanese Patent Applications No. 2023-107632, filed on Jun. 30, 2023, the entire contents of which are hereby incorporated by reference.

### BACKGROUND

### Technical Field

The present disclosure relates to a light-emitting device.

### Background Art

Light-emitting devices using light-emitting elements such as LEDs can easily achieve high light emission efficiency and thus are used in a wide range of fields such as lighting, in-vehicle lighting, displays, and backlights for liquid crystal displays. Japanese Patent Application Publication No. 2023-051717 discloses a light-emitting device including a first light-emitting element, a second light-emitting element, a first lens portion located above the first light-emitting element, and a second lens portion located above the second light-emitting element.

### SUMMARY

There is a demand for light-emitting devices having further improved light extraction efficiency. An object of an embodiment according to the present invention is to provide a light-emitting device that can have improved light extraction efficiency.

According to an aspect of the present invention, a light-emitting device includes a support; a first light-emitting element and a second light-emitting element that are aligned in a first direction and located on the support; a light-transmissive member including a first lens portion overlapping the first light-emitting element in a top view, a second lens portion overlapping the second light-emitting element in a top view, and a first connecting portion connecting the first lens portion and the second lens portion; and a reflective member overlapping the first connecting portion in a top view.

A light-emitting device of an embodiment of the present invention can have improved light extraction efficiency.

### BRIEF DESCRIPTION OF DRAWINGS

FIG. 1 is a schematic top view of a light-emitting device according to a first embodiment.

FIG. 2 is a schematic cross-sectional view of a light-emitting device taken along line II-II in FIG. 1.

FIG. 3 is a schematic front view of the light-emitting device according to the first embodiment.

FIG. 4 is a schematic right side view of the light-emitting device according to the first embodiment.

FIG. 5 is a schematic top view of a support, light-emitting elements, and wires according to the first embodiment.

FIG. 6 is a schematic cross-sectional view of the light-emitting device taken along line VI-VI in FIG. 1.

FIG. 7 is a schematic top view of the support, the light-emitting elements, the wires, a reflective member, a light absorbing member, and a second covering member according to the first embodiment.

FIG. 8 is a schematic cross-sectional view of the light-emitting device taken along line VIII-VIII in FIG. 1.

FIG. 9 is a schematic enlarged view of the vicinity of a first lens portion and a second lens portion of the light-emitting device according to the first embodiment.

FIG. 10 is a schematic top view of a modified example of the light-emitting device according to the first embodiment.

FIG. 11 is a schematic top view of a light-emitting device according to a second embodiment.

FIG. 12 is a schematic top view of a support, light-emitting elements, and wires according to the second embodiment.

FIG. 13 is a schematic cross-sectional view of the light-emitting device taken along line XIII-XIII in FIG. 11.

FIG. 14 is a schematic top view of the support, the light-emitting elements, the wires, a reflective member, a light absorbing member, and a second covering member according to the second embodiment.

FIG. 15 is a schematic top view of a light-emitting device according to a third embodiment.

FIG. 16 is a schematic right side view of the light-emitting device according to the third embodiment.

### DETAILED DESCRIPTION

Embodiments are described below with reference to the drawings. The drawings schematically illustrate the embodiments, and thus scales, intervals, positional relationships, or the like of members may be exaggerated, or illustration of some of the members may be omitted. In the present specification, a direction of an arrow on a Z axis is defined as an upward direction and a direction opposite to the direction of the arrow on the Z axis is defined as a downward direction. Viewing an object from above is referred to as a top view, and the top view is synonymous with a plan view. As a cross-sectional view, an end view illustrating only a cut surface may be illustrated.

In the following description, components having substantially the same function may be denoted by the same reference characters and a description thereof may be omitted. Terms indicating a specific direction or position (for example, “upper,” “lower,” and other terms including those terms) may be used. These terms are used merely for ease of understanding of relative directions or positions in the referenced drawing. As long as the relative direction or position is the same as that described in the referenced drawing using the term such as “upper” or “lower” in drawings other than the drawings of the present disclosure, actual products, and the like, components need not be arranged in the same manner as that in the referenced drawing. In the present specification, “parallel” includes not only a case in which two straight lines, sides, surfaces, etc., or their extensions do not intersect, but also a case in which two straight lines, sides, surfaces, or the like intersect at an angle of 10° or less. In the present specification, a positional relationship expressed by using the term “on” includes a case in which one object is in contact with the other object and also a case in which one object is not in contact with but located above the other object.

### First Embodiment

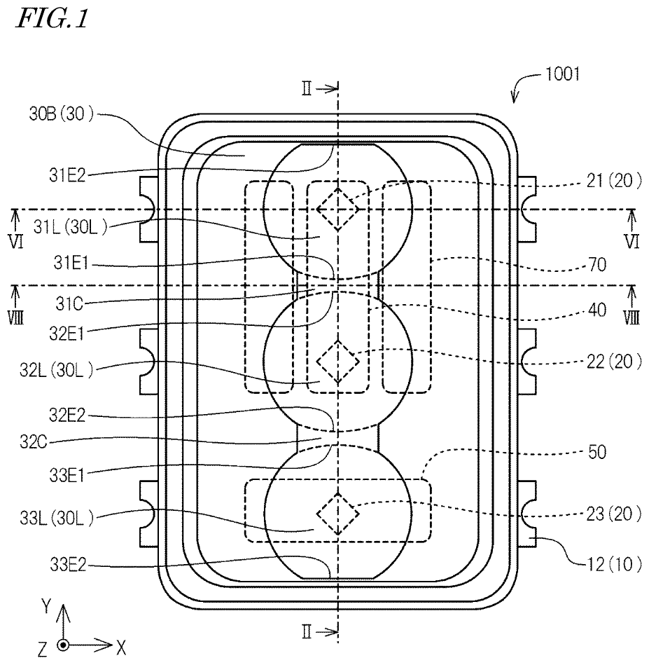

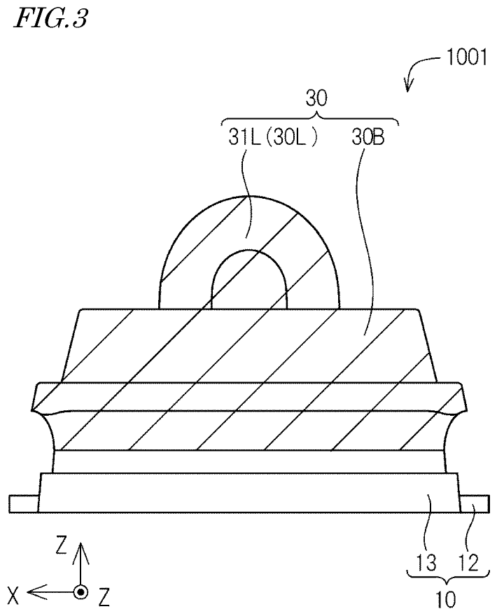

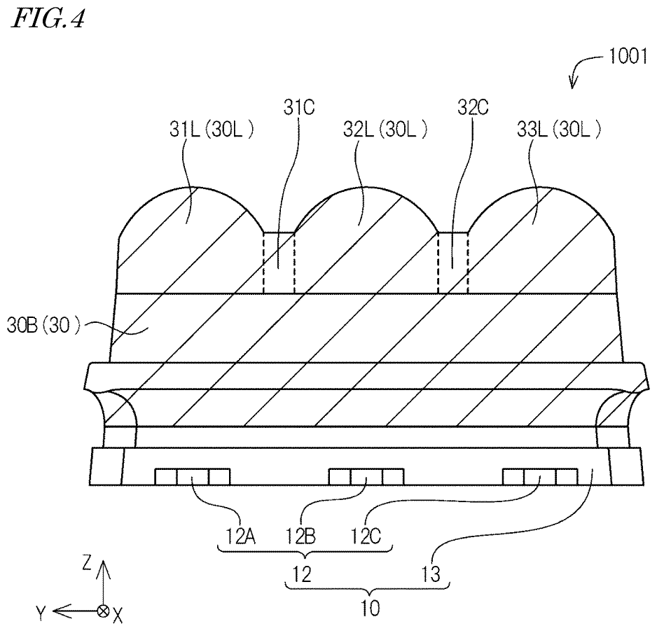

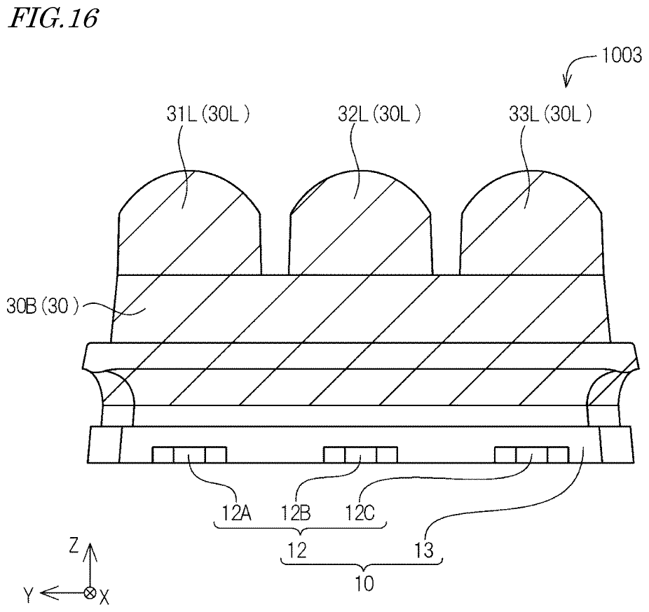

A light-emitting device 1001 according to a first embodiment is described with reference to FIGS. 1 to 10. FIG. 1 is a schematic view of the light-emitting device 1001 viewed from a light-emitting surface side thereof. In FIGS. 3 and 4, a light-transmissive member 30 is hatched. Also in FIG. 16 to be described below, the light-transmissive member 30 is hatched. As illustrated in FIG. 1, two directions that are parallel to the light-emitting surface of the light-emitting device 1001 and are orthogonal to each other are referred to as an X direction and a Y direction. A direction orthogonal to the X direction and the Y direction is referred to as a Z direction. In the present specification, the direction of an arrow on an X axis may be referred to as a +X direction, the direction opposite to the direction of the arrow on the X axis may be referred to as a —X direction, the direction of an arrow on a Y axis may be referred to as a +Y direction, and the direction opposite to the direction of the arrow on the Y axis may be referred to as a −Y direction. In the present specification, in an XY plane being a plane parallel to the X direction and the Y direction, the direction inclined from the X direction at an angle of equal to or larger than 0° and smaller than 360° may be referred to as a lateral direction, and the Z direction may be referred to as an up-down direction.

The light-emitting device 1001 includes a support 10, light-emitting elements 20, the light-transmissive member 30, and a reflective member 40. The light-emitting elements 20 include a first light-emitting element 21 and a second light-emitting element 22. The first light-emitting element 21 is located on the support 10. The second light-emitting element 22 is located on the support 10. The first light-emitting element and the second light-emitting element are aligned in a first direction. The light-transmissive member 30 includes a first lens portion 31L, a second lens portion 32L, and a first connecting portion 31C. In a top view, the first lens portion 31L overlaps the first light-emitting element 21. In a top view, the second lens portion 32L overlaps the second light-emitting element 22. The first connecting portion 31C connects the first lens portion 31L and the second lens portion 32L. In a top view, the reflective member 40 overlaps the first connecting portion 31C.

The light-transmissive member 30 includes the first connecting portion 31C connecting the first lens portion 31L and the second lens portion 32L, and accordingly the surface area of the light-transmissive member 30 is easily increased. With this configuration, light from the first light-emitting element 21 and/or the second light-emitting element 22 is easily extracted from the light-transmissive member 30 to the outside of the light-emitting device 1001. This facilitates improvement in the light extraction efficiency of the light-emitting device 1001. The reflective member 40 overlaps the first connecting portion 31C in a top view, and accordingly the area of the reflective member 40 in a top view is easily increased. With this configuration, absorption of light from the first light-emitting element 21 and/or the second light-emitting element 22 by the support 10 is easily reduced. This facilitates improvement in the light extraction efficiency of the light-emitting device 1001.

Elements constituting the light-emitting device 1001 are described below in detail.

### Support 10

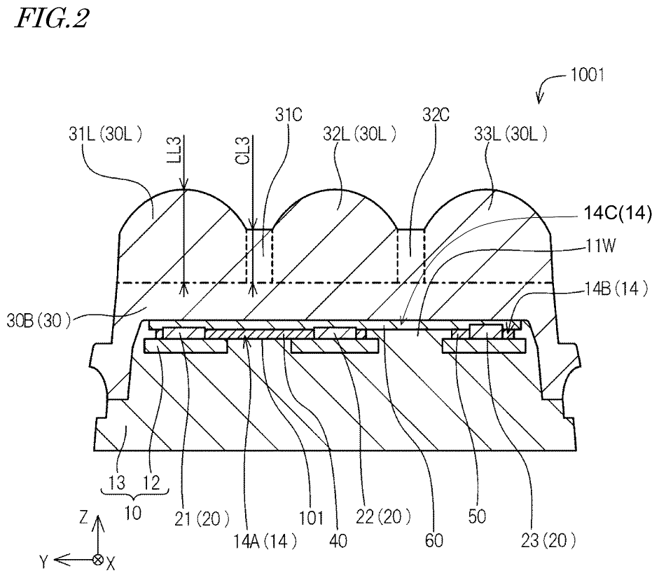

The support 10 is a member on which the light-emitting element 20 is disposed. The support 10 and the light-emitting element 20 are bonded to each other with a known bonding member such as resin, solder, or conductive paste. As illustrated in FIG. 2, in the first embodiment, the first light-emitting element 21 and the second light-emitting element 22 are bonded to a first surface 101 of the support 10. As illustrated in FIGS. 2 to 5, the support 10 of the first embodiment includes a plurality of leads 12 and a resin member 13. The first surface 101 of the support 10 is defined by parts of upper surfaces of the leads 12 and a part of an upper surface of the resin member 13. The upper surfaces of the plurality of leads 12 and the upper surface of the resin member 13 defining the first surface 101 of the support 10 are at least partially coplanar with each other. In the present specification, the term “coplanar” includes variation within ±15 μm. The upper surface of the lead 12 may have a recessed portion.

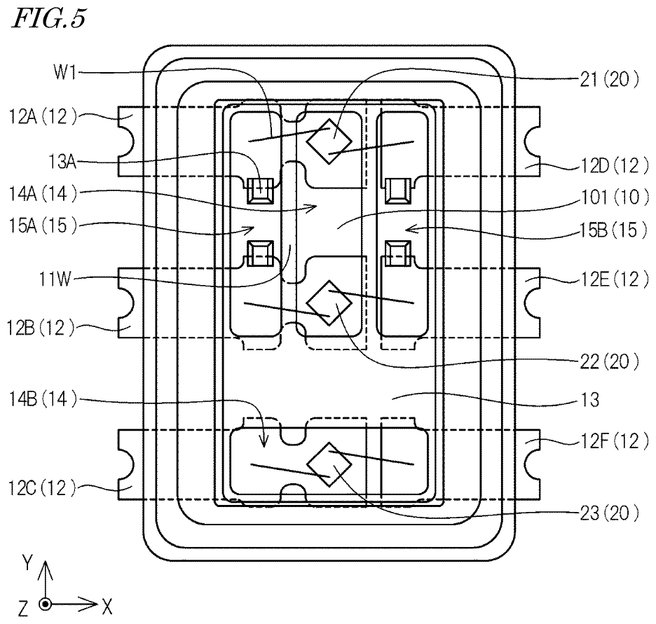

The lead 12 has conductivity and serves as an electrode for supplying power to the light-emitting element 20. As illustrated in FIG. 5, the leads 12 of the first embodiment include a first lead 12A, a second lead 12B, a third lead 12C, a fourth lead 12D, a fifth lead 12E, and a sixth lead 12F. The first light-emitting element 21 is located on the first lead 12A. The second light-emitting element 22 is located on the second lead 12B. A third light-emitting element 23 to be described below is located on the third lead 12C. The first light-emitting element 21 is electrically connected to the first lead 12A and the fourth lead 12D via a wire W1. The second light-emitting element 22 is electrically connected to the second lead 12B and the fifth lead 12E via a wire. The third light-emitting element 23 is electrically connected to the third lead 12C and the sixth lead 12F via a wire. Preferably, the first light-emitting element 21, the second light-emitting element 22, and the third light-emitting element 23 can be driven independently from each other. This facilitates adjustment in the chromaticity of the light-emitting device 1001. The plurality of light-emitting elements 20 may be connected in series, may be connected in parallel, or may be connected in a combination of series connection and parallel connection.

The first lead 12A, the second lead 12B, and the third lead 12C are aligned in the first direction (Y direction). The fourth lead 12D, the fifth lead 12E, and the sixth lead 12F are aligned in the first direction (Y direction). The first lead 12A and the fourth lead 12D are aligned in the second direction (X direction). The second lead 12B and the fifth lead 12E are aligned in the second direction (X direction). The third lead 12C and the sixth lead 12F are aligned in the second direction (X direction).

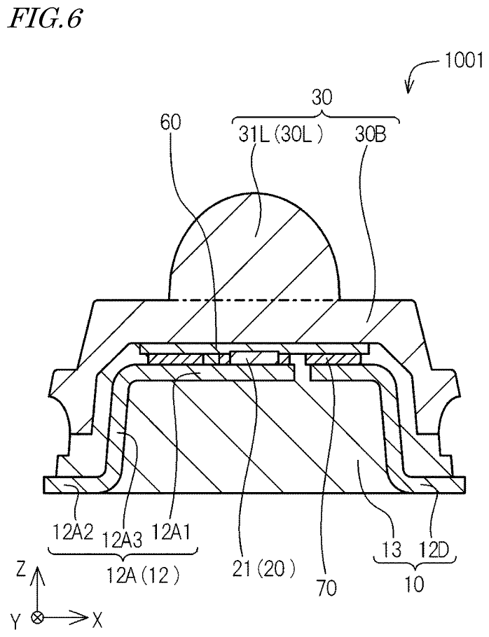

As illustrated in FIG. 6, the first lead 12A of the first embodiment is bent to include a first lead first portion 12A1 located on an upper surface side of the support 10, a first lead second portion 12A2 located on a lower surface side of the support 10, and a first lead third portion 12A3 located between the first lead first portion 12A1 and the first lead second portion 12A2. At least a part of an upper surface of the first lead first portion 12A1 is exposed from the resin member 13 and the first light-emitting element 21 is disposed thereon. At least a part of a lower surface of the first lead second portion 12A2 is exposed from the resin member 13 and serves as a mounting surface when the light-emitting device 1001 is fixed to a mounting substrate. Each of the second lead, the third lead, the fourth lead, the fifth lead, and the sixth lead is bent including a first portion located on the upper surface side of the support, a second portion located on the lower surface side of the support, and a third portion located between the first portion and the second portion.

As a base material of the lead 12, for example, any of metals such as copper, aluminum, gold, silver, iron, nickel, alloys thereof, phosphor bronze, and iron-containing copper can be used. The base material may have a single-layer structure or a layered structure (a clad material, for example). Particularly, copper, which is inexpensive and has high heat dissipation properties, is preferably used as the base material. The lead may include a metal layer on a surface of the base material. The metal layer contains, for example, gold, silver, aluminum, nickel, palladium, rhodium, copper, and alloys thereof. The metal layer may be provided on the entirety of a surface of the lead or may be provided on a part of a surface of the lead. A metal layer on an upper surface of the lead and a metal layer on a lower surface of the lead can be different from each other. In one example, the metal layer formed on the upper surface of the lead is composed of a plurality of layers including a nickel layer and a silver layer, and the metal layer formed on the lower surface of the lead does not include nickel. The metal layer made of gold or the like and formed on the upper surface of the lead can be thicker than the metal layer made of gold or the like and formed on the lower surface of the lead.

When a metal layer containing silver is formed at the outermost surface of the lead 12, a protective layer made of silicon oxide or the like is preferably provided on the surface of the metal layer containing silver. This allows for inhibiting the color of the metal layer containing silver from changing due to sulfur components in the atmosphere, or the like. The protective layer can be formed by, for example, a vacuum process such as sputtering, but other known methods may also be used.

The resin member 13 has insulating properties. The resin member 13 holds the plurality of leads 12. As a resin material serving as a base material of the resin member 13, a known material such as a thermoplastic resin or a thermosetting resin can be used. Examples of the thermoplastic resin that can be used include an aromatic polyamide resin, a polyphthalamide resin (PPA), a sulfone resin, a polyamide-imide resin (PAI), a polyketone resin (PK), a polycarbonate resin, polyphenylene sulfide (PPS), a liquid crystal polymer (LCP), an ABS resin, and a PBT resin. Examples of the thermosetting resin that can be used include an epoxy resin, a modified epoxy resin, a silicone resin, and a modified silicone resin.

In the resin member 13, a colorant may be added to the resin material serving as a base material. Various dyes and pigments are preferably used as the colorant. Specific examples include Cr₂O₃, MnO₂, Fe₂O₃, carbon black, titanium black, and the like. The amount of the colorant to be added may be, for example, in a range from 0.3 mass % to 3.5 mass %, preferably in a range from 1.0 mass % to 2.5 mass % with respect to the resin material serving as a base material. For example, as the resin member 13, polyphthalamide (PPA) to which 2 mass % of dark-colored particles of carbon or the like are added may be used. The resin member 13 may contain a glass filler or the like. When the resin member 13 contains a glass filler, the strength of the resin member 13 is easily improved. The glass filler may be dark-colored with carbon black or the like.

When the light-emitting device 1001 is used in a display device such as an LED display, the resin member 13 is preferably made of a dark-colored resin. With the resin member 13 made of a dark-colored resin such as a black resin or a gray resin, reduction in reflection of external light such as sunlight or indoor light by the resin member 13 is facilitated. Accordingly, a decrease in the contrast ratio between when the light-emitting device 1001 is lit and when the light-emitting device 1001 is not lit, which is caused by the reflection of the external light, can be easily inhibited. The resin member 13 of the first embodiment is made of a dark-colored resin. Note that, in the present specification, “dark colors” refer to colors having a color value of 4.0 or less in the Munsell color system (20 hues). The hue is not particularly limited, and the chroma may be appropriately determined as necessary. It is preferable that the color value is 4.0 or less and the chroma is 4.0 or less.

Light from the light-emitting device 1001 of the first embodiment is extracted to the outside mainly from the upper surface side of the light-emitting device 1001. Therefore, at least a part of the upper surface of the resin member 13 is preferably dark-colored. When at least a part of the upper surface of the resin member 13 located on the light-emitting surface side is dark-colored, a decrease in the contrast ratio between when the light-emitting device 1001 is lit and when the light-emitting device 1001 is not lit, which is caused by reflection of external light by the upper surface of the light-emitting device 1001, can be easily inhibited. The resin member 13 may be dark-colored, or may be a white-colored resin printed with dark-colored ink. Alternatively, the resin member 13 may be formed using resins with two colors of a dark-colored resin and a white-colored resin. The white-colored resin includes, for example, a light-reflective material in the resin material serving as a base material. As the light-reflective material, a member that is less likely to absorb light from the light-emitting element 20 and has a large refractive index difference with respect to the resin material serving as a base material is preferably used. This facilitates reduction in absorption of the light from the light-emitting element 20 by the resin member 13. Examples of the light-reflective material that can be used include particles of titania, silica, alumina, zinc oxide, magnesium oxide, zirconia, yttria, calcium fluoride, magnesium fluoride, niobium pentoxide, barium titanate, tantalum pentoxide, barium sulfate, glass, or the like. In one example, the resin member 13 is made of only a white-colored resin.

As the support 10, a wiring substrate including a substrate and a wiring may be used. The substrate can be formed using resin, ceramic, glass, or the like. As the resin, a known material such as the above-mentioned thermosetting resin or thermoplastic resin can be used. Examples of the ceramic include aluminum oxide, aluminum nitride, zirconium oxide, zirconium nitride, titanium oxide, titanium nitride, and mixtures thereof. The wiring can be formed of copper, iron, nickel, tungsten, chromium, aluminum, silver, gold, titanium, palladium, rhodium, or an alloy thereof. A single layer or multiple layers of any of these metals or alloys thereof may be used.

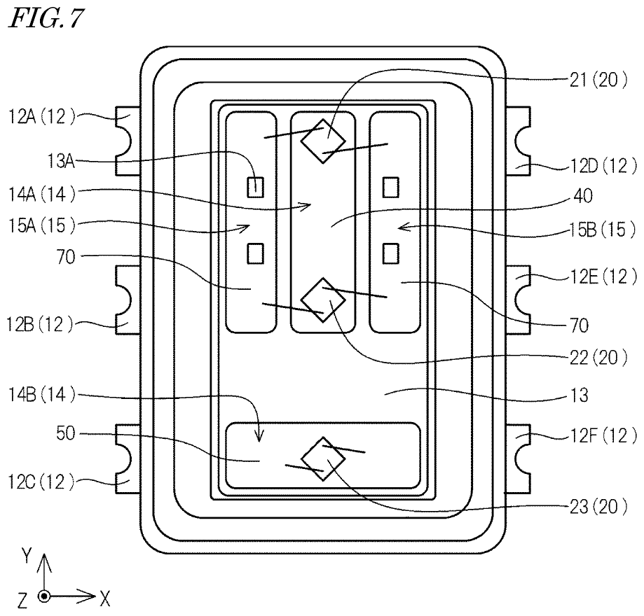

As illustrated in FIGS. 2 and 5, the support 10 of the first embodiment includes one continuous element recessed portion 14 for accommodating the light-emitting element 20. The continuous element recessed portion 14 of the first embodiment includes a first element recessed portion 14A, a second element recessed portion 14B and a portion 14C connecting the first element recessed portion 14A and the second element recessed portion 14B. The recessed portion 14C connecting the first element recessed portion 14A and the second element recessed portion 14B has a first covering member 60 located therein as shown in FIG. 2 and to be described below. The first element recessed portion 14A and the second element recessed portion 14B are located at a lower side of the element recessed portion 14. The first element recessed portion 14A and the second element recessed portion 14B are separated from each other by a sidewall 11W. The first element recessed portion 14A is defined by the sidewall 11W and the first surface 101. The sidewall 11W may be formed using a material different from that of the resin member 13, or the sidewall 11W may be formed using the resin member 13 as in the first embodiment. The first light-emitting element 21 and the second light-emitting element 22 are located in the first element recessed portion 14A. The third light-emitting element 23 is located in the second element recessed portion 14B. As illustrated in FIG. 7, the reflective member 40 is located in the first element recessed portion 14A. The reflective member 40 of the first embodiment is in contact with the sidewall 11W defining the first element recessed portion 14A. Thus, the shape of the reflective member 40 in a top view can be easily controlled by the first element recessed portion 14A. This facilitates improvement in the yield of the light-emitting device 1001. In the first embodiment, light from the first light-emitting element 21 and the second light-emitting element 22 does not impinge on an inner surface of the sidewall 11W due to the reflective member 40 located in the first element recessed portion 14A. Light from the first light-emitting element 21 or the second light-emitting element 22 may impinge on the inner surface of the sidewall 11W. As illustrated in FIG. 7, a light absorbing member 50 to be described below is located in the second element recessed portion 14B. Thus, the shape of the light absorbing member 50 in a top view can be easily controlled by the second element recessed portion 14B. This facilitates improvement in the yield of the light-emitting device 1001.

As illustrated in FIG. 5, the support 10 of the first embodiment includes at least one wire recessed portion 15 in which one end of the wire is located. The element recessed portion 14 of the first embodiment includes the at least one wire recessed portion 15. The wire recessed portion 15 is located at a lower side of the element recessed portion 14. A part of the wire recessed portion 15 is defined by the upper surface of at least one lead 12. The upper surface of the lead 12 that defines a part of the wire recessed portion 15 is electrically connected to the wire. The at least one wire recessed portion 15 of the first embodiment includes a first wire recessed portion 15A and a second wire recessed portion 15B. As illustrated in FIG. 7, a second covering member 70 to be described below is located in the first wire recessed portion 15A and the second wire recessed portion 15B. The second covering member 70 of the first embodiment is in contact with the lateral surface defining the wire recessed portion 15. Thus, the shape of the second covering member 70 in a top view can be easily controlled by the first wire recessed portion 15A and/or the second wire recessed portion 15B. This facilitates improvement in the yield of the light-emitting device 1001.

As illustrated in FIG. 5, the resin member 13 preferably includes a covering resin portion 13A that covers the upper surface of the lead 12 in the wire recessed portion 15. This configuration facilitates improvement in the adhesion between the lead 12 and the resin member 13. Including the covering resin portion 13A that covers the upper surface of the lead 12 facilitates reduction of deformation of the lead 12 due to heat.

### Light-Emitting Element 20

The light-emitting device 1001 includes the plurality of light-emitting elements 20 located on the support 10. In the present embodiment, the light-emitting device 1001 includes the first light-emitting element 21, the second light-emitting element 22, and the third light-emitting element 23. The number of light-emitting elements 20 included in the light-emitting device 1001 may be one, two, three, or four or more.

The light-emitting element 20 includes a semiconductor layered body. The semiconductor layered body includes, for example, an element substrate made of sapphire, gallium nitride, gallium arsenide, aluminum nitride, or the like, an n-type semiconductor layer, a p-type semiconductor layer, and a light-emitting layer interposed between the n-type semiconductor layer and the p-type semiconductor layer, which are disposed on the element substrate. The light-emitting element 20 further includes an n-side electrode electrically connected to the n-type semiconductor layer, and a p-side electrode electrically connected to the p-type semiconductor layer. The n-side electrode and the p-side electrode form a part of an upper surface of the light-emitting element 20. In another example, the light-emitting element 20 does not include the element substrate made of sapphire, gallium nitride, gallium arsenide, aluminum nitride, or the like. This facilitates reduction in the size of the light-emitting element 20.

When the light-emitting element 20 includes a light-transmissive element substrate (hereinafter, referred to as a light-transmissive substrate) made of sapphire, gallium nitride, or the like as the element substrate, light of the light-emitting element 20 is likely to exit also through a lateral surface of the light-transmissive substrate. Therefore, when the light-emitting element 20 includes the light-transmissive substrate, the ratio of light extracted from the lateral surface of the light-emitting element to light extracted from the upper surface of the light-emitting element is likely to increase. As the element substrate of the light-emitting element 20 that emits blue light or green light, a light-transmissive substrate is often used. In the present specification, the light-transmissive element substrate means an element substrate having a transmittance of 60% or more at a peak wavelength of a light-emitting element.

When the light-emitting element 20 includes a light-shielding element substrate (hereinafter, referred to as a light-shielding substrate) made of gallium arsenide or aluminum nitride and having light-blocking properties as the element substrate, light of the light-emitting element 20 is less likely to exit through a lateral surface of the light-shielding substrate. Therefore, when the light-emitting element 20 includes the light-shielding substrate as the element substrate, the ratio of light extracted from the lateral surface of the light-emitting element to light extracted from the upper surface of the light-emitting element is more likely to be smaller than that when the light-emitting element 20 includes the light-transmissive substrate as the element substrate. As the element substrate of the light-emitting element 20 that emits red light, the light-shielding substrate is often used. In the present specification, the light-shielding element substrate means an element substrate having a transmittance of 50% or less at a peak wavelength of a light-emitting element.

As a structure of the light-emitting layer, a structure including a single active layer such as a double heterostructure and a single quantum well (SQW) structure may be employed, or a structure including a group of active layers such as a multiple quantum well (MQW) structure may be employed. The light-emitting layer is configured to emit visible light or ultraviolet light. The light-emitting layer is configured to emit light, as visible light, from blue light to red light. As the semiconductor layered body including the light-emitting layer, for example, InₓAl_{y}Ga_{1-x-y}N (0≤x, 0≤y, x+y≤1) can be included. The semiconductor layered body can include at least one light-emitting layer that can achieve the light emission described above. For example, the semiconductor layered body may have a structure including one or more light-emitting layers between the n-type semiconductor layer and the p-type semiconductor layer, or may have a structure in which a structure including the n-type semiconductor layer, the light-emitting layer, and the p-type semiconductor layer in order is repeated multiple times. When the semiconductor layered body includes a plurality of light-emitting layers, the semiconductor layered body may include light-emitting layers having different peak wavelengths, or may include light-emitting layers having the same peak wavelength. The term “having the same peak wavelength” includes a variation of approximately several nanometers, for example. A combination of such light-emitting layers can be selected as appropriate, and, for example, when the semiconductor layered body includes two light-emitting layers, the light-emitting layers can be selected from combinations of blue light and blue light, green light and green light, red light and red light, ultraviolet light and ultraviolet light, blue light and green light, blue light and red light, green light and red light, and the like. The light-emitting layer may include a plurality of active layers having different peak wavelengths, or may include a plurality of active layers having the same peak wavelength.

The light-emitting element 20 can have any appropriate shape in a top view. The light-emitting element 20 may have, for example, a shape such as a circular, triangular, quadrangular, hexagonal, or octagonal shape in a top view. When the shape of the light-emitting element 20 in a top view is quadrangular, a pair of outer edges of the light-emitting element 20 may be parallel to the first direction (Y direction) or may be inclined with respect to the first direction (Y direction). In the first embodiment, the pair of outer edges of the light-emitting element 20 are inclined at 45° with respect to the first direction (Y direction).

The first light-emitting element 21 emits light with a first peak wavelength. A wavelength at which an output value of a spectrum of light emitted from the first light-emitting element 21 is the highest is defined as the first peak wavelength. For example, the first peak wavelength is in a range from 430 nm to 480 nm. The first light-emitting element 21 of the first embodiment emits blue light. The first light-emitting element 21 of the first embodiment includes a light-transmissive substrate, and light is easily extracted from a lateral surface of the light-emitting element. The first light-emitting element 21 may emit green light, red light, or the like. The first light-emitting element 21 may include a light-shielding substrate.

The second light-emitting element 22 emits light with a second peak wavelength different from the first peak wavelength. A wavelength at which an output value of a spectrum of light emitted from the second light-emitting element 22 is the highest is defined as the second peak wavelength. For example, the second peak wavelength is in a range from 500 nm to 580 nm. The second light-emitting element 22 of the present embodiment emits green light. The second light-emitting element 22 of the first embodiment includes a light-transmissive substrate, and thus light is easily extracted from a lateral surface of the light-emitting element. The second light-emitting element 22 may emit blue light, red light, or the like. The second light-emitting element 22 may include a light-shielding substrate.

The third light-emitting element 23 emits light with a third peak wavelength different from the first peak wavelength and the second peak wavelength. A wavelength at which an output value of a spectrum of light emitted from the third light-emitting element 23 is the highest is referred to as the third peak wavelength. For example, the third peak wavelength is in a range from 600 nm to 780 nm. The third light-emitting element 23 of the present embodiment emits red light. The third light-emitting element 23 of the third embodiment includes a light-shielding substrate, and thus light is less likely to be extracted from a lateral surface of the light-emitting element. The third light-emitting element 23 may emit blue light, green light, or the like. The third light-emitting element 23 may include a light-transmissive substrate. For example, when the first light-emitting element 21 emits blue light, the second light-emitting element 22 emits green light, and the third light-emitting element 23 emits red light, full color light can be emitted from the light-emitting device 1001, so that the color reproducibility is easily improved. The peak wavelengths of the first light-emitting element 21, the second light-emitting element 22, and the third light-emitting element 23 may be the same.

The light-emitting device may include a wavelength conversion member that covers the upper surface and/or the lateral surfaces of the light-emitting element 20. The wavelength conversion member contains a phosphor and can convert light from the light-emitting element into light with a given peak wavelength. For example, when the first light-emitting element 21, the second light-emitting element 22, and the third light-emitting element 23 emit blue light, a first wavelength conversion member covering the upper surface and/or the lateral surfaces of the second light-emitting element may include a green phosphor and a second wavelength conversion member covering the upper surface and/or the lateral surfaces of the third light-emitting element may include a red phosphor such that the light-emitting device can emit full color light. The green phosphor included in the first wavelength conversion member converts at least a part of the blue light emitted from the second light-emitting element 22 into green light. The red phosphor included in the second wavelength conversion member converts at least a part of the blue light emitted from the third light-emitting element 23 into red light.

Examples of the phosphor included in each of the wavelength conversion members include an yttrium aluminum garnet-based phosphor (for example, (Y,Gd)₃(Al,Ga)₅O₁₂:Ce), a lutetium aluminum garnet-based phosphor (for example, Lu₃(Al,Ga)₅O₁₂:Ce), a terbium aluminum garnet-based phosphor (for example, Tb₃(Al,Ga)₅O₁₂:Ce), a CCA-based phosphor (for example, Ca₁₀(PO₄)₆Cl₂:Eu), an SAE-based phosphor (for example, Sr₄Al₁₄O₂₅:Eu), a chlorosilicate-based phosphor (for example, Ca₈MgSi₄O₁₆Cl₂:Eu), a silicate-based phosphor (for example, (Ba,Sr,Ca,Mg)₂SiO₄:Eu), oxynitride-based phosphors such as a β-SiAlON-based phosphor (for example, (Si,Al)₃(O,N)⁴:Eu) and an α-SiAlON-based phosphor (for example, Ca (Si,Al)₁₂(O,N)₁₆:Eu), nitride-based phosphors such as an LSN-based phosphor (for example, (La, Y)₃Si₆N₁₁:Ce), a BSESN-based phosphor (for example, (Ba,Sr)₂Si₅N₈:Eu), an SLA-based phosphor (for example, SrLiAl₃N₄:Eu), a CASN-based phosphor (for example, CaAlSiN₃:Eu), and an SCASN-based phosphor (for example, (Sr,Ca)AlSiN₃:Eu), fluoride-based phosphors such as a KSF-based phosphor (for example, K₂SiF₆:Mn), a KSAF-based phosphor (for example, K₂(Si₁₋ₓAlₓ)F₆₋ₓ:Mn, where x satisfies 0 <x<1), and an MGF-based phosphor (for example, 3.5 MgO·0.5 MgF₂·GeO₂:Mn), a quantum dot having a perovskite structure (for example, (Cs,FA,MA) (Pb,Sn) (F,Cl,Br,I)₃, where FA and MA represent formamidinium and methylammonium, respectively), a II-VI group quantum dot (for example, CdSe), a III-V group quantum dot (for example, InP), a quantum dot having a chalcopyrite structure (for example, (Ag,Cu) (In,Ga)(S,Se)₂), and the like. As the phosphor included in each of the wavelength conversion members, one type of phosphor may be used, or a plurality of types of phosphors may be used.

As illustrated in FIG. 1, in the first embodiment, the first light-emitting element 21 and the second light-emitting element 22 are aligned in the first direction. In the present specification, the expression that the first light-emitting element 21 and the second light-emitting element 22 are aligned in the first direction means that at least a part of the first light-emitting element 21 and at least a part of the second light-emitting element 22 are located on a straight line along the first direction. As illustrated in FIG. 1, the first light-emitting element 21 and the third light-emitting element 23 are aligned in the first direction.

### Reflective Member 40

The reflective member 40 is a member having reflectivity with respect to light from the light-emitting element 20. In the first embodiment, the reflective member 40 is located in the first element recessed portion 14A. In the present specification, having reflectivity means that a reflectance for the peak wavelength of a light-emitting element is 50% or more, unless otherwise specified. When the light-emitting device includes a plurality of light-emitting elements, it means that the reflectance for the peak wavelength of any one of the plurality of light-emitting elements is 50% or more. The reflective member 40 includes, for example, a base material and a light-reflective material dispersed in the base material. As the base material of the reflective member 40, the same material as the resin material of the resin member 13 or a known material such as glass can be used. As the light-reflective material of the reflective member 40, a known material such as the same material as the light-reflective material of the resin member 13 can be used.

In the first embodiment, the reflective member 40 overlaps the first connecting portion 31C of the light-transmissive member 30 in a top view. With this configuration, the area of the reflective member 40 in a top view is easily increased, which facilitates reduction in absorption of light from the light-emitting element 20 by the support 10. This facilitates improvement in the light extraction efficiency of the light-emitting device 1001. The reflective member 40 overlaps the first connecting portion 31C of the light-transmissive member 30 in a top view, which allows light from the first light-emitting element 21 and/or the second light-emitting element 22 reflected by the reflective member 40 to be easily extracted from the first connecting portion 31C to the outside of the light-emitting device 1001. This facilitates improvement in the light extraction efficiency of the light-emitting device 1001.

As illustrated in FIG. 1, the reflective member 40 is preferably located around the first light-emitting element 21, and overlaps the first lens portion 31L in a top view. This configuration facilitates reduction in absorption of light from the first light-emitting element 21 by the support 10. When the first light-emitting element 21 includes a light-transmissive substrate, the reflective member 40 is particularly preferably located around the first light-emitting element 21. With this configuration, light traveling in the lateral direction from the lateral surface of the first light-emitting element 21 is more likely to be reflected by the reflective member 40, which facilitates reduction in absorption of light from the first light-emitting element 21 by the support 10.

In the present specification, the expression “the reflective member 40 is located around the light-emitting element 20” means that the reflective member 40 is located close to a lateral surface of the light-emitting element 20 in a top view. The reflective member 40 may or may not be in direct contact with a lateral surface of the first light-emitting element 21. The reflective member 40 is preferably in contact with a lateral surface of the first light-emitting element 21 and/or the second light-emitting element 22. This configuration facilitates reduction in absorption of light from the first light-emitting element 21 and/or the second light-emitting element 22 by the support 10.

In a top view, the reflective member 40 may be located close to a part of the lateral surface of the first light-emitting element 21, or may surround the first light-emitting element 21 without a break. In a top view, the reflective member 40 preferably surrounds the first light-emitting element 21 without a break. This configuration facilitates reduction in absorption of light from the first light-emitting element 21 by the support 10. Similarly, in a top view, the reflective member 40 preferably surrounds the second light-emitting element 22 without a break.

At least a part of the upper surface of the first light-emitting element 21 is exposed from the reflective member 40. The entire upper surface of the first light-emitting element 21 is preferably exposed from the reflective member 40. With this configuration, light from the upper surface of the first light-emitting element 21 is easily extracted to the outside of the light-emitting device 1001.

As illustrated in FIG. 1, the reflective member 40 is preferably located around the second light-emitting element 22, and overlaps the second lens portion 32L in a top view. This configuration facilitates reduction in absorption of light from the second light-emitting element 22 by the support 10. When the second light-emitting element 22 includes a light-transmissive substrate, the reflective member 40 is particularly preferably located around the second light-emitting element 22. With this configuration, light traveling in the lateral direction from the lateral surface of the second light-emitting element 22 is easily reflected by the reflective member 40, which facilitates reduction in absorption of light from the second light-emitting element 22 by the support 10.

In a top view, the reflective member 40 may be located close to a part of the lateral surface of the second light-emitting element 22, or may surround the second light-emitting element 22 without a break. In a top view, the reflective member 40 preferably surrounds the second light-emitting element 22 without a break. This configuration facilitates reduction in absorption of light from the second light-emitting element 22 by the support 10.

At least a part of the upper surface of the second light-emitting element 22 is exposed from the reflective member 40. The entire upper surface of the second light-emitting element 22 is preferably exposed from the reflective member 40. With this configuration, light from the upper surface of the second light-emitting element 22 is easily extracted from the first lens portion to the outside of the light-emitting device.

The reflective member located around the first light-emitting element 21 and the reflective member located around the second light-emitting element 22 may be separate members or may be integrally formed. In the first embodiment, one reflective member 40 is located around the first light-emitting element 21 and the second light-emitting element 22.

### Light-Transmissive Member 30

The light-transmissive member 30 is a member that is light-transmissive to light from the light-emitting element 20. In the present specification, being light-transmissive means that the transmittance for the peak wavelength of a light-emitting element is 60% or more, unless otherwise specified. When the light-emitting device includes a plurality of light-emitting elements, the transmittance for the peak wavelength of a given light-emitting element needs to be 60% or more. As a base material of the light-transmissive member 30, the same material as the resin material of the resin member 13 or a known material such as glass can be used. The light-transmissive member 30 may contain a light-reflective material in order to diffuse light from the light-emitting element to reduce unevenness in light intensity. As the light-reflective material of the light-transmissive member 30, a known material such as the same material as the light-reflective material of the resin member 13 can be used.

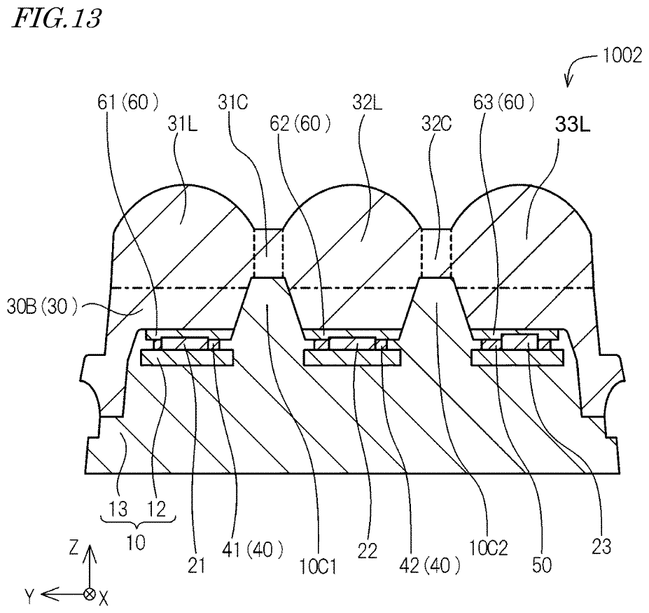

The light-transmissive member 30 includes a base portion 30B and lens portions 30L. In FIGS. 2, 6, and 8, the boundary between the base portion 30B and the lens portion 30L is indicated by an alternate long and short dash line. Also, in FIG. 13 to be described below, the boundary between the base portion 30B and the lens portion 30L is indicated by an alternate long and short dash line. In the light-transmissive member 30 of the first embodiment, the base portion 30B and the lens portion 30L are integrally formed as a single body. For example, the base portion 30B and the lens portion 30L can be integrally formed by cast-molding, transfer-molding, or the like. The base portion 30B and the lens portion 30L may be separate bodies. The base portion 30B covers the upper surface of the support 10. In a top view, the base portion 30B of the first embodiment overlaps the first light-emitting element 21, the second light-emitting element 22, and the third light-emitting element 23. The lens portion 30L has a function of controlling the direction of light that is to be emitted. The lens portion 30L is located on an upper surface of the base portion 30B. The lens portion 30L has a convex shape extending upward from the base portion 30B. At least a part of the surface of the lens portion 30L preferably includes a curved surface. When at least a part of the surface of the lens portion 30L has a convex shape including a curved surface, it is easy to efficiently extract light from the light-emitting element 20 to the outside of the light-transmissive member 30. A part of the surface of the lens portion 30L may be flat. The shape and arrangement of the lens portion 30L can be appropriately selected in consideration of light distribution characteristics, light extraction efficiency, or the like of the light-emitting device. The lens portion 30L may be a concave shape, a Fresnel lens, or the like.

The base portion 30B of the light-transmissive member 30 may have any appropriate surface roughness. The surface roughness of at least a part of the base portion 30B of the light-transmissive member 30 is preferably rougher than the surface roughness of at least a part of the lens portion 30L. With this configuration, external light reflected by the base portion 30B of the light-transmissive member 30 is easily scattered. This makes it possible to reduce strong reflection of external light in a specific direction by the base portion 30B of the light-transmissive member 30.

One or more lens portions 30L may be included in the light-transmissive member 30. The lens portions 30L of the first embodiment include the first lens portion 31L, the second lens portion 32L, and a third lens portion 33L. In a top view, the first lens portion 31L overlaps the first light-emitting element 21. With the light-transmissive member 30 including the first lens portion 31L, the distribution of light emitted from the first light-emitting elements 21 is easily controlled. In a top view, the second lens portion 32L overlaps the second light-emitting element 22. In a top view, the third lens portion 33L overlaps the third light-emitting element 23.

The first lens portion 31L, the second lens portion 32L, and the third lens portion 33L may be formed of the same material or may be formed of different materials. For example, the first lens portion 31L may be colored in a color similar to the color of light with the first peak wavelength emitted by the first light-emitting element 21. This structure allows a part of external light in a range of wavelengths far from the first peak wavelength of the first light-emitting element 21 to be less easily reflected by the first lens portion 31L when the first light-emitting element 21 is not lit, and allows light from the first light-emitting element 21 to be less easily absorbed by the first lens portion 31L when the first light-emitting element 21 is lit. Similarly, the second lens portion 32L may be colored in a color similar to the color of light with the second peak wavelength emitted by the second light-emitting element 22, and the third lens portion 33L may be colored in a color similar to the color of light with the third peak wavelength emitted by the third light-emitting element 23. In the present specification, “similar colors” mean that, in the Munsell color system (20 hues), the hues thereof are within three adjacent ranges in the hue circle, the color values thereof are within three adjacent ranges, and the chromas thereof are within three adjacent ranges.

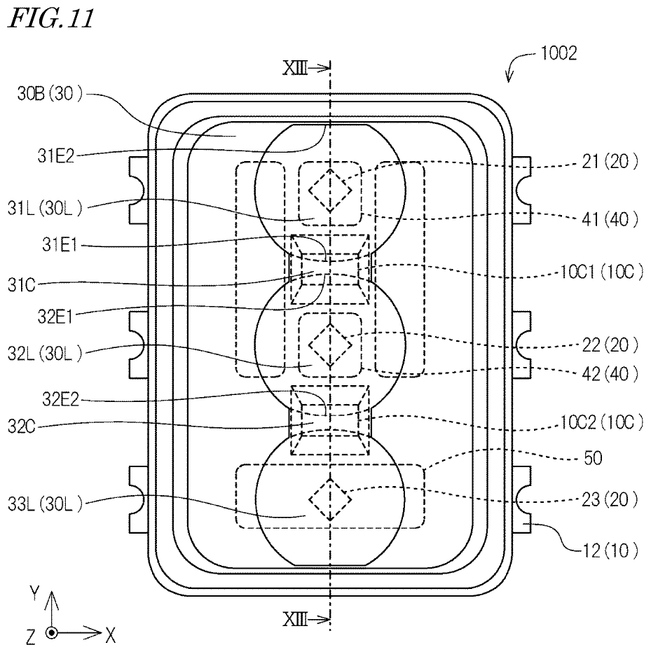

The light-transmissive member 30 of the first embodiment includes the first connecting portion 31C that connects the first lens portion 31L and the second lens portion 32L. In the present specification, the first connecting portion 31C and a second connecting portion 32C to be described below are parts of the lens portion 30L. In the present specification, the first connecting portion 31C and/or the second connecting portion 32C may be referred to as a connecting portion. In FIGS. 1, 2, 4, 9, and 10, the boundary between the lens portion 30L and each connecting portion is indicated by a broken line. Also, in FIGS. 11 and 13 to be described below, the boundary between the lens portion 30L and each connecting portion is indicated by a broken line. With the light-transmissive member 30 including the first connecting portion 31C, increase in the surface area of the light-transmissive member 30 can be facilitated. With this configuration, light from the first light-emitting element 21 and/or the second light-emitting element 22 is easily extracted from the light-transmissive member 30 to the outside of the light-emitting device 1001. This facilitates improvement in the light extraction efficiency of the light-emitting device 1001. With the light-transmissive member 30 including the first connecting portion 31C, the mechanical strength of the first lens portion 31L and the second lens portion 32L is easily improved.

The light-transmissive member 30 of the first embodiment includes the second connecting portion 32C that connects the second lens portion 32L and the third lens portion 33L. With the light-transmissive member 30 including the second connecting portion 32C, the surface area of the light-transmissive member 30 is easily increased. With this configuration, light from the second light-emitting element 22 and/or the third light-emitting element 23 is easily extracted from the light-transmissive member 30 to the outside of the light-emitting device 1001. This facilitates improvement in the light extraction efficiency of the light-emitting device 1001. With the light-transmissive member 30 including the second connecting portion 32C, the mechanical strength of the second lens portion 32L and the third lens portion 33L is easily improved.

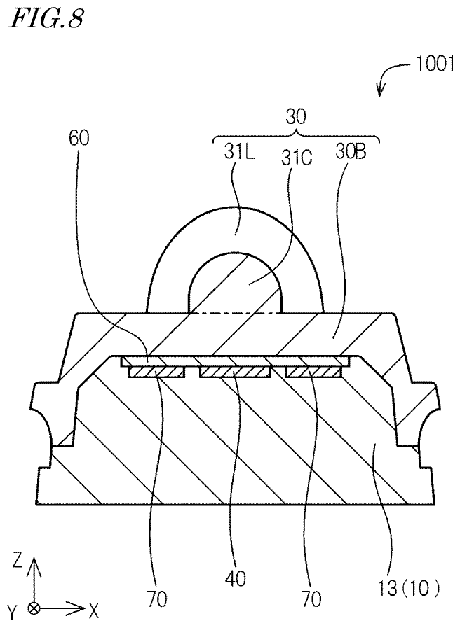

The first connecting portion 31C and the second connecting portion 32C can have any appropriate shape in a cross-sectional view. As illustrated in FIG. 8, the shape of the first connecting portion 31C in cross-sectional view preferably includes a convex shape including a curved surface. This configuration allows light from the first light-emitting element 21 and/or the second light-emitting element 22 to be easily extracted to the outside of the first connecting portion 31C. Similarly, the shape of the second connecting portion 32C in cross-sectional view preferably includes a convex shape including a curved surface.

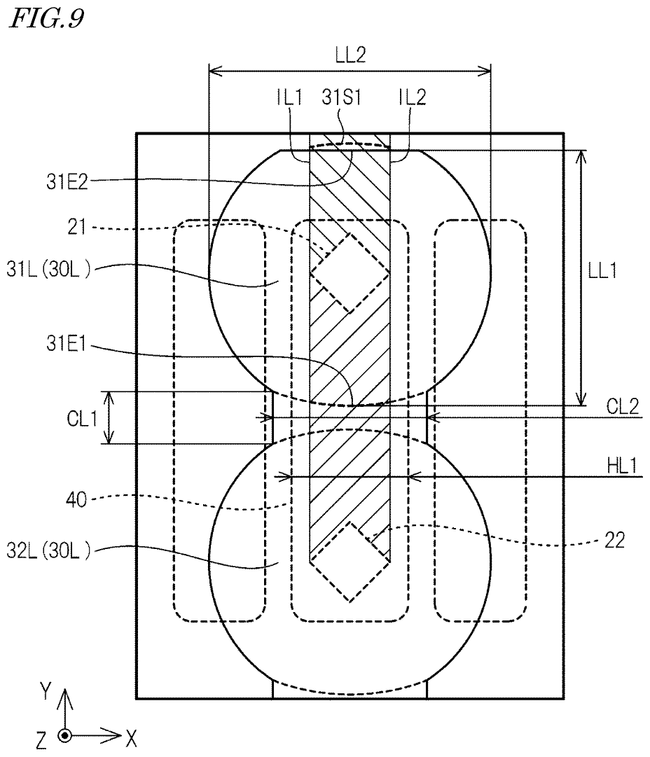

As illustrated in FIG. 9, a first connecting portion first length CL1 being the maximum length of the first connecting portion 31C in the first direction (Y direction) is preferably in a range from 0.1 times to 0.5 times a first lens portion first length LL1 being the maximum length of the first lens portion 31L in the first direction (Y direction). When the first connecting portion first length CL1 is equal to or greater than 0.1 times the first lens portion first length LL1, the surface area of the first connecting portion 31C is easily increased. This facilitates improvement in the light extraction efficiency of the light-emitting device 1001. When the first connecting portion first length CL1 is equal to or less than 0.5 times the first lens portion first length LL1, the light-emitting device in the first direction (Y direction) is easily reduced in size. Similarly, the first connecting portion first length CL1 is preferably in a range from 0.1 times to 0.5 times the maximum length of the second lens portion 32L and/or the third lens portion 33L in the first direction (Y direction). The maximum length of the second connecting portion 32C in the first direction (Y direction) is preferably in a range from 0.1 times to 0.5 times the maximum length of the first lens portion 31L, the second lens portion 32L, and/or the third lens portion 33L in the first direction (Y direction).

As illustrated in FIG. 9, a first connecting portion second length CL2 being the maximum length of the first connecting portion 31C in the second direction (X direction) is preferably in a range from 0.2 times to 0.8 times a first lens portion second length LL2 being the maximum length of the first lens portion 31L in the second direction (X direction). When the first connecting portion second length CL2 is equal to or greater than 0.2 times the first lens portion second length LL2, the surface area of the first connecting portion 31C is easily increased. This facilitates improvement in the light extraction efficiency of the light-emitting device 1001. When the first connecting portion second length CL2 is equal to or less than 0.8 times the first lens portion second length LL2, the surface area of the first lens portion 31L is easily increased. This allows the first lens portion 31L to easily control the distribution of light emitted from the first light-emitting element 21. Similarly, the first connecting portion second length CL2 is preferably in a range from 0.2 times to 0.8 times the maximum length of the second lens portion 32L and/or the third lens portion 33L in the second direction (X direction). The maximum length of the second connecting portion 32C in the second direction (X direction) is preferably in a range from 0.2 times to 0.8 times the maximum length of the first lens portion 31L, the second lens portion 32L, and/or the third lens portion 33L in the second direction (X direction).

As illustrated in FIG. 9, the first connecting portion second length CL2 being the maximum length of the first connecting portion 31C in the second direction (X direction) is preferably longer than a reflective portion first length HLI being the maximum length of the reflective member 40 in the second direction (X direction). This configuration facilitates increase in the surface area of the first connecting portion 31C of the light-transmissive member 30. Thus, light from the first light-emitting element 21 and/or the second light-emitting element 22 is easily extracted from the light-transmissive member 30 to the outside of the light-emitting device 1001. Similarly, the maximum length of the second connecting portion 32C in the second direction (X direction) is preferably longer than the reflective portion first length HL1.

The reflective portion first length HL1 is preferably shorter than the first lens portion second length LL2. With this structure, a decrease in the contrast ratio between when the light-emitting device 1001 is lit and when the light-emitting device 1001 is not lit, which is caused by reflection of external light by the reflective member 40, can be easily inhibited. Similarly, the reflective portion first length HLI is preferably shorter than the maximum length of the second lens portion 32L and/or the third lens portion 33L in the second direction (X direction).

As illustrated in FIG. 2, a first connecting portion third length CL3 being the maximum length of the first connecting portion 31C in the up-down direction (Z direction) is preferably in a range from 0.3 times to 0.7 times a first lens portion third length LL3 being the maximum length of the first lens portion 31L in the up-down direction (Z direction). When the first connecting portion third length CL3 is equal to or greater than 0.3 times the first lens portion third length LL3, the surface area of the first connecting portion 31C is easily increased. This facilitates improvement in the light extraction efficiency of the light-emitting device 1001. When the first connecting portion third length CL3 is equal to or less than 0.7 times the first lens portion third length LL3, the surface area of the first lens portion 31L is easily increased. This allows the first lens portion 31L to easily control the distribution of light emitted from the first light-emitting element 21. Similarly, the first connecting portion third length CL3 is preferably in a range from 0.3 times to 0.7 times the maximum length of the second lens portion 32L and/or the third lens portion 33L in the up-down direction (Z direction). The maximum length of the second connecting portion 32C in the up-down direction (Z direction) is preferably in a range from 0.3 times to 0.7 times the maximum length of the first lens portion 31L, the second lens portion 32L, and/or the third lens portion 33L in the up-down direction (Z direction).

As illustrated in FIGS. 1 and 9, in a top view, an outer edge of the first lens portion 31L includes a first lens first outer edge portion 31E1 located between the first light-emitting element 21 and the second light-emitting element 22, and a first lens second outer edge portion 31E2 located on a side opposite to the first lens first outer edge portion 31E1 with respect to the center of the first light-emitting element 21. In the present specification, the portion located between the first light-emitting element 21 and the second light-emitting element 22 means a portion located on a plurality of straight lines connecting a part of the first light-emitting element 21 and a part of the second light-emitting element 22. In FIG. 9, a range of locations on a plurality of straight lines connecting a part of the first light-emitting element 21 and a part of the second light-emitting element 22 is indicated by right-upward hatching. The “first lens second outer edge portion 31E2 located on the side opposite to the first lens first outer edge portion 31E1 with respect to the center of the first light-emitting element 21” means an outer edge of the first lens portion 31L located between a first virtual straight line IL1 and a second virtual straight line IL2 with respect to the center of the first light-emitting element 21 and located on the virtual line segment 31S1 side. The first virtual straight line IL1 connects a point located furthest in the —X direction within a virtual line segment 31S1 point-symmetrical to the first lens first outer edge portion 31E1 with a point located furthest in —X direction within the first light-emitting element 21. The second virtual straight line IL2 connects a point located furthest in the +X direction within the virtual line segment 31S1 point-symmetrical to the first lens first outer edge portion 31E1 with a point located furthest in the +X direction within the first light-emitting element 21. In FIG. 9, a range of locations on the virtual line segment 31S1 side and located between the first virtual straight line ILI and the second virtual straight line IL2 is indicated by left-upward hatching. As used herein, the center of the first light-emitting element 21 is the centroid of the first light-emitting element 21 in a top view.

In a top view, at least a part of the first lens first outer edge portion 31E1 preferably overlaps the reflective member 40, and at least a part of the first lens second outer edge portion 31E2 is preferably spaced apart from the reflective member 40. When at least a part of the first lens first outer edge portion 31E1 overlaps the reflective member 40 in a top view, the area of the reflective member 40 in a top view is easily increased. This configuration facilitates reduction in absorption of light from the first light-emitting element 21 and/or the second light-emitting element 22 by the support 10. When at least a part of the first lens second outer edge portion 31E2 is spaced apart from the reflective member 40, a decrease in the contrast ratio between when the light-emitting device 1001 is lit and when the light-emitting device 1001 is not lit, which is caused by reflection by the reflective member 40, is easily inhibited. In a top view, the entire first lens first outer edge portion 31E1 preferably overlaps the reflective member 40. This configuration facilitates reduction in absorption of light from the first light-emitting element 21 and/or the second light-emitting element 22 by the support 10. In a top view, the entire first lens second outer edge portion 31E2 is preferably spaced apart from the reflective member 40. With this structure, a decrease in the contrast ratio between when the light-emitting device 1001 is lit and when the light-emitting device 1001 is not lit, which is caused by reflection by the reflective member 40, can be easily inhibited.

For example, when a display device using the light-emitting device 1001 is viewed from below, the light-emitting device 1001 may be viewed from the −Y direction side. In such a case, in a region around the first light-emitting element 21, a portion of the reflective member 40 located on the +Y direction side may be more visible than a portion of the reflective member 40 located on the −Y direction side due to refraction on the surface of the first lens portion 31L. In the first embodiment, the first lens second outer edge portion 31E2 is spaced apart from the reflective member 40, which facilitates allowing the area of the portion of the reflective member 40 located on the +Y direction side to be smaller than the area of the portion of the reflective member 40 located on the −Y direction side in the region around the first light-emitting element 21. Accordingly, a decrease in the contrast ratio between when the light-emitting device 1001 is lit and when the light-emitting device 1001 is not lit, which is caused by reflection of external light by the portion of the reflective member 40 located on the +Y direction side in the region around the first light-emitting element 21, can be easily inhibited. In the first embodiment, in a top view, within a region of the reflective member 40 overlapping the first lens portion 31L, the area of a portion of the reflective member 40 located on the +Y direction side with respect to the center of the first light-emitting element 21 is smaller than the area of a portion of the reflective member 40 located on the −Y direction side. In general, the luminous intensity of a light-emitting element that emits blue light is often lower than the luminous intensity of a light-emitting element that emits green light or red light. Therefore, in order to reduce a decrease in the contrast ratio between when a light-emitting device is lit and when the light-emitting device is not lit, the reflection of external light is often required to be reduced particularly around the light-emitting element that emits blue light. In the first embodiment, in a top view, within the region of the reflective member 40 overlapping the first lens portion 31L, the area of a portion of the reflective member 40 located on the +Y direction side with respect to the center of the first light-emitting element 21 that emits blue light is smaller than the area of a portion of the reflective member 40 located on the −Y direction side. This results in a structure that allows a decrease in the contrast ratio between when the light-emitting device 1001 is lit and when the light-emitting device 1001 is not lit, which is caused by reflection of external light by the reflective member 40 around the first light-emitting element that emits blue light, to be easily reduced.

As illustrated in FIG. 1, in a top view, an outer edge of the second lens portion 32L includes a second lens first outer edge portion 32E1 located between the first light-emitting element 21 and the second light-emitting element 22, and a second lens second outer edge portion 32E2 located on a side opposite to the second lens first outer edge portion 32E1 with respect to the center of the second light-emitting element 22.

In a top view, at least a part of the second lens first outer edge portion 32E1 preferably overlaps the reflective member 40, and at least a part of the second lens second outer edge portion 32E2 is preferably spaced apart from the reflective member 40. When at least a part of the second lens first outer edge portion 32E1 overlaps the reflective member 40 in a top view, increase in the area of the reflective member 40 in a top view can be facilitated. This configuration facilitates reduction in absorption of light from the first light-emitting element 21 and/or the second light-emitting element 22 by the support 10. When at least a part of the second lens second outer edge portion 32E2 is spaced apart from the reflective member 40, a decrease in the contrast ratio between when the light-emitting device 1001 is lit and when the light-emitting device 1001 is not lit, which is caused by reflection of external light by the reflective member 40, can be easily inhibited. In a top view, the entire second lens first outer edge portion 32E1 preferably overlaps the reflective member 40. This configuration facilitates reduction in absorption of light from the first light-emitting element 21 and/or the second light-emitting element 22 by the support 10. In a top view, the entire second lens second outer edge portion 32E2 is preferably spaced apart from the reflective member 40. This facilitates inhibiting a decrease in the contrast ratio between when the light-emitting device 1001 is lit and when the light-emitting device 1001 is not lit, which is caused by reflection of external light by the reflective member 40.

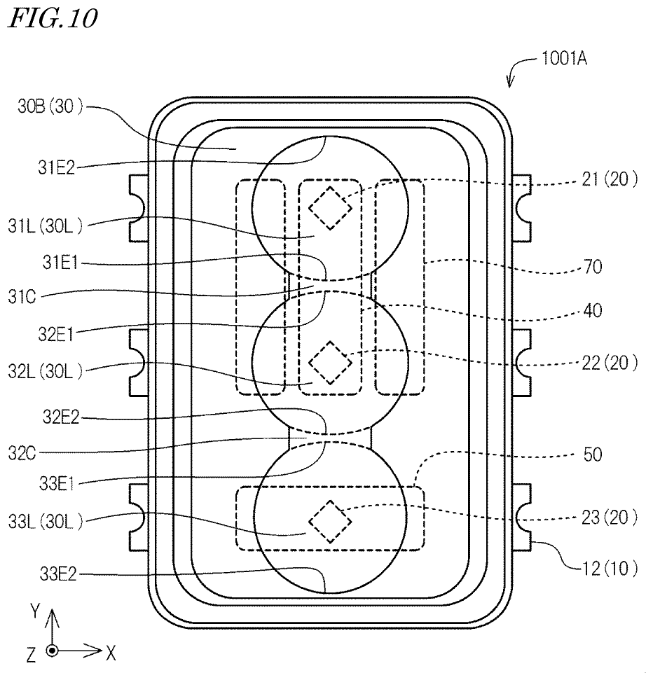

At least a part of a lateral surface of the first lens portion 31L including the first lens second outer edge portion 31E2 is preferably a surface orthogonal to the first direction (Y direction). In other words, at least a part of the lateral surface of the first lens portion 31L including the first lens second outer edge portion 31E2 is preferably a surface parallel to the second direction. This makes it easier to reduce the light-emitting device 1001 in size in the first direction (Y direction). As in a light-emitting device 1001A illustrated in FIG. 10, the lateral surface of the first lens portion 31L including the first lens second outer edge portion 31E2 may be a curved surface. When the lateral surface of the first lens portion 31L including the first lens second outer edge portion 31E2 is a curved surface, it is easy to efficiently extract light from the first light-emitting element 21 to the outside of the light-transmissive member 30.

As illustrated in FIG. 1, in a top view, an outer edge of the third lens portion 33L includes a third lens first outer edge portion 33E1 located between the second light-emitting element 22 and the third light-emitting element 23, and a third lens second outer edge portion 33E2 located on a side opposite to the third lens first outer edge portion 33E1 with respect to the center of the third light-emitting element 23. At least a part of a lateral surface of the third lens portion 33L including the third lens second outer edge portion 33E2 is preferably a surface orthogonal to the first direction (Y direction). This facilitates reduction in size of the light-emitting device 1001 in the first direction (Y direction). As in the light-emitting device 1001A illustrated in FIG. 10, the lateral surface of the third lens portion 33L including the third lens second outer edge portion 33E2 may be a curved surface. When the lateral surface of the third lens portion 33L including the third lens second outer edge portion 33E2 is a curved surface, light from the third light-emitting element 23 is facilitated to be efficiently extracted to the outside of the light-transmissive member 30.

### Light Absorbing Member 50

The light absorbing member 50 is a member that absorbs light from the light-emitting element 20. In the first embodiment, the light absorbing member 50 is located in the second element recessed portion 14B. In the present specification, the term “absorb” means that an absorptance with respect to the peak wavelength of a light-emitting element is 50% or more. When the light-emitting device includes a plurality of light-emitting elements, an absorptance with respect to the peak wavelength of a given light-emitting element needs to be 50% or more. The light absorbing member 50 includes, for example, a base material and a colorant dispersed in the base material. As the base material of the light absorbing member 50, the same material as the resin material of the resin member 13 or a known material such as glass can be used. As the colorant of the light absorbing member 50, a known material such as the same material as the colorant of the resin member 13 can be used. For example, a resin material obtained by adding a glass filler colored with carbon black to an epoxy-modified silicone resin material can be used as the light absorbing member 50. The amount of the colored glass filler is, for example, in a range from 1 mass % to 5 mass %, preferably in a range from 2 mass % to 4 mass % with respect to the resin material serving as the base material. The light absorbing member 50 is preferably a dark-colored member. The light absorbing member 50 preferably has a color value of 4.0 or less and a chroma of 4.0 or less in the Munsell color system (20 hues).

The light absorbing member 50 of the first embodiment is located around the third light-emitting element 23. With this configuration, the area of the light absorbing member 50 in a top view is easily increased. This facilitates inhibiting a decrease in the contrast ratio between when the light-emitting device 1001 is lit and when the light-emitting device 1001 is not lit, which is caused by reflection of external light by the surface of the support 10. In a top view, the light absorbing member 50 overlaps the third lens portion 33L. The light absorbing member 50 may or may not be in direct contact with a lateral surface of the third light-emitting element 23. The light absorbing member 50 is preferably in contact with the lateral surface of the third light-emitting element 23. This facilitates inhibiting a decrease in the contrast ratio between when the light-emitting device 1001 is lit and when the light-emitting device 1001 is not lit, which is caused by reflection of external light by the surface of the support 10.

### First Covering Member 60

The light-emitting device 1001 further includes the first covering member 60 located between the light-emitting element 20 and the light-transmissive member 30 in the up-down direction (Z direction). The first covering member 60 is located in the element recessed portion 14C. The first covering member 60 is a member that is light-transmissive to light from the light-emitting element 20. With the first covering member 60 located between the light-emitting element 20 and the light-transmissive member 30, deterioration of the light-transmissive member 30 due to light from the light-emitting element 20 can be easily reduced. As a base material of the first covering member 60, a known material such as the same material as the resin material of the resin member 13 can be used. In one example, an epoxy resin may be used as the material of the light-transmissive member 30, and a silicone resin may be used as the material of the first covering member 60. In another example, a phenyl silicone resin may be used as the material of the light-transmissive member 30, and a dimethyl silicone resin may also be used as the material of the first covering member 60. The first covering member 60 may contain a light-reflective material in order to reduce unevenness in light intensity by diffusing light from the light-emitting element. As the light-reflective material of the first covering member 60, a known material such as the same material as the light-reflective material of the resin member 13 can be used.

In a top view, the first covering member 60 preferably overlaps the first light-emitting element 21, the second light-emitting element 22, and the third light-emitting element 23. That is, the first covering member 60 preferably covers the upper surfaces of the first light-emitting element 21, the second light-emitting element 22, and the third light-emitting element 23. This facilitates inhibiting deterioration of the light-transmissive member 30 caused by light from the first light-emitting element 21, the second light-emitting element 22, and the third light-emitting element 23.

The refractive index of the base material of the first covering member 60 is not particularly limited, but is preferably higher than the refractive index of the base material of the light-transmissive member 30. This configuration facilitates reduction of reflection of light from the light-emitting element 20 at an interface between the first covering member 60 and the light-transmissive member 30, and thus facilitates improvement in the light extraction efficiency of the light-emitting device 1001.

### Second Covering Member 70

The light-emitting device 1001 further includes the second covering member 70 that covers one end portion of the wire connected to the support 10. In the first embodiment, the second covering member 70 is located in each of the first wire recessed portion 15A and the second wire recessed portion 15B. The second covering member 70 is preferably a member that absorbs light from the light-emitting element 20. This facilitates inhibiting a decrease in the contrast ratio between when the light-emitting device 1001 is lit and when the light-emitting device 1001 is not lit, which is caused by reflection of external light by the surface of the support 10. As a material of the second covering member 70, a known material such as the same material as the material of the light absorbing member 50 can be used. The second covering member 70 is preferably a dark-colored member. The second covering member 70 preferably has a color value of 4.0 or less and a chroma of 4.0 or less in the Munsell color system (20 hues).

### Second Embodiment

A light-emitting device 1002 of the second embodiment is described with reference to FIGS. 11 to 14. As illustrated in FIG. 11, the light-emitting device 1002 of the second embodiment is different from the light-emitting device 1001 of the first embodiment in that the support 10 includes at least one protruding portion 10C. The light-emitting device 1002 of the second embodiment is further different from the light-emitting device 1001 of the first embodiment in that the first connecting portion 31C and each reflective member 40 are spaced apart from each other in a top view.

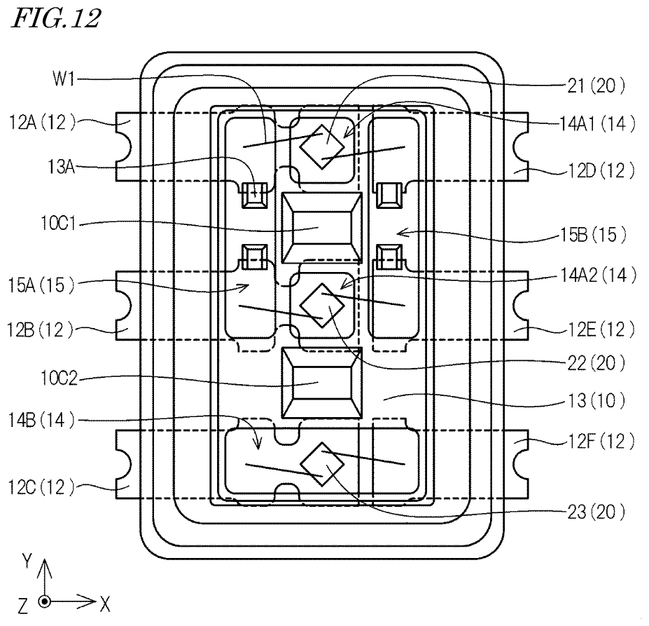

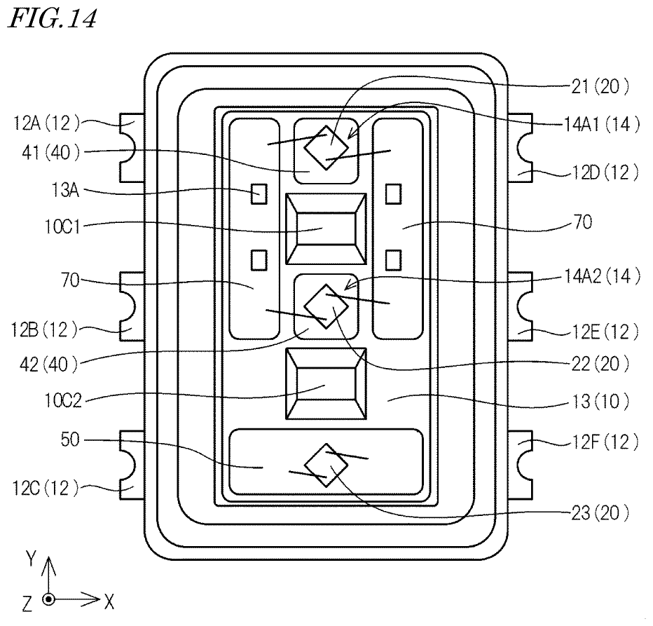

As illustrated in FIG. 12, element recessed portions 14 of the support 10 of the second embodiment includes a first element first recessed portion 14A1 in which the first light-emitting element 21 is located and a second element first recessed portion 14A2 in which the second light-emitting element 22 is located. As illustrated in FIGS. 13 and 14, reflective members 40 of the second embodiment includes a first reflective member 41 located around the first light-emitting element 21 and a second reflective member 42 spaced apart from the first reflective member 41 and located around the second light-emitting element 22. The first reflective member 41 is located in the first element first recessed portion 14A1. The second reflective member 42 is located in the second element first recessed portion 14A2.

In the second embodiment, the at least one protruding portion 10C of the support 10 includes a first protruding portion 10C1 and a second protruding portion 10C2. As illustrated in FIG. 11, the first protruding portion 10C1 is located between the first light-emitting element 21 and the second light-emitting element 22 in a top view. The support 10 includes the first protruding portion 10C1, which facilitates reduction of extraction of light emitted by the first light-emitting element 21 from the second lens portion 32L and/or extraction of light emitted by the second light-emitting element 22 from the first lens portion 31L. Accordingly, the ratio of light emitted from the first light-emitting element 21 to the outside through the first lens portion 31L in the light emitted from the first light-emitting element 21 to the outside of the light-transmissive member 30 is more likely to be increased. This facilitates the first lens portion 31L to control the light from the first light-emitting element 21. Similarly, with the support 10 including the first protruding portion 10C1, light from the second light-emitting element 22 is easily controlled by the second lens portion 32L.

As illustrated in FIG. 13, a part of the first protruding portion 10C1 preferably overlaps the first lens portion 31L and/or the second lens portion 32L in the up-down direction (Z direction). This facilitates reduction of extraction of light emitted by the first light-emitting element 21 from the second lens portion 32L and/or extraction of light emitted by the second light-emitting element 22 from the first lens portion 31L.

As illustrated in FIG. 11, the second protruding portion 10C2 is located between the second light-emitting element 22 and the third light-emitting element 23 in a top view. The support 10 includes the second protruding portion 10C2, which facilitates reduction of extraction of light emitted by the second light-emitting element 22 from the third lens portion 33L and/or extraction of light emitted by the third light-emitting element 23 from the second lens portion 32L. Accordingly, the ratio of light emitted from the second light-emitting element 22 to the outside through the second lens portion 32L in the light emitted from the second light-emitting element 22 to the outside of the light-transmissive member 30 is more likely to be increased. This facilitates the second lens portion 32L to control the light from the second light-emitting element 22. Similarly, with the support 10 includes the second protruding portion 10C2, light from the third light-emitting element 23 is easily controlled by the third lens portion 33L.

As illustrated in FIG. 13, a part of the second protruding portion 10C2 preferably overlaps the second lens portion 32L and/or the third lens portion 33L in the up-down direction (Z direction). This facilitates reduction of extraction of light emitted by the second light-emitting element 22 from the third lens portion 33L and/or extraction of light emitted by the third light-emitting element 23 from the second lens portion 32L.

The maximum length of the first protruding portion 10C1 in the second direction (X direction) is preferably shorter than the first connecting portion second length being the maximum length of the first connecting portion 31C in the second direction (X direction). In other words, the first connecting portion second length is preferably longer than the maximum length of the first protruding portion 10C1 in the second direction (X direction). With this configuration, the surface area of the light-transmissive member 30 is easily increased. Thus, light from the first light-emitting element 21 and/or the second light-emitting element 22 is easily extracted from the light-transmissive member 30 to the outside of the light-emitting device 1002. Similarly, the maximum length of the second protruding portion 10C2 in the second direction is preferably shorter than a second connecting portion second length, which is the maximum length of the second connecting portion 32C in the second direction (X direction).

The maximum length of the first protruding portion 10C1 in the second direction (X direction) is preferably longer than the maximum length of each of the first light-emitting element 21 and the second light-emitting element 22 in the second direction (X direction). This configuration allows the first protruding portion 10C1 to facilitate reduction of extraction of light emitted by the first light-emitting element 21 from the second lens portion 32L and extraction of light emitted by the second light-emitting element 22 from the first lens portion 31L are easily reduced by. Similarly, the maximum length of the second protruding portion 10C2 in the second direction is preferably longer than the second light-emitting element 22 and/or the third light-emitting element 23 in the second direction (X direction).

The maximum length of the first protruding portion 10C1 in the second direction (X direction) is preferably longer than the maximum length of each of the first reflective member 41 and the second reflective member 42 in the second direction (X direction). This configuration allows the first protruding portion 10C1 to facilitate reduction of extraction of light emitted by the first light-emitting element 21 from the second lens portion 32L and extraction of light emitted by the second light-emitting element 22 from the first lens portion 31. Similarly, the maximum length of the second protruding portion 10C2 in the second direction is preferably longer than the maximum length of the second reflective member 42 in the second direction (X direction).

In a top view, the first covering member 60 of the second embodiment includes a first element covering member 61 overlapping the first light-emitting element 21, a second element covering member 62 overlapping the second light-emitting element 22, and a third element covering member 63 overlapping the third light-emitting element 23. That is, the first covering member 60 includes the first element covering member 61 covering the upper surface of the first light-emitting element 21, the second element covering member 62 covering the upper surface of the second light-emitting element 22, and the third element covering member 63 covering the upper surface of the third light-emitting element 23. The first element covering member 61, the second element covering member 62, and the third element covering member 63 may be formed of the same material or may be formed of different materials. For example, the first element covering member 61 may be colored in a color similar to the color of light with the first peak wavelength emitted by the first light-emitting element 21. This facilitates reduction of reflection of a part of external light, which is in a range of wavelengths far from the first peak wavelength of the first light-emitting element 21, by the first element covering member 61 when the first light-emitting element 21 is not lit, and facilitates reduction of absorption of light from the first light-emitting element 21 by the first element covering member 61 when the first light-emitting element 21 is lit. Similarly, the second element covering member 62 may be colored in a color similar to the color of light with the second peak wavelength emitted by the second light-emitting element 22, and the third element covering member 63 may be colored in a color similar to the color of light with the third peak wavelength emitted by the third light-emitting element 23.

### Third Embodiment

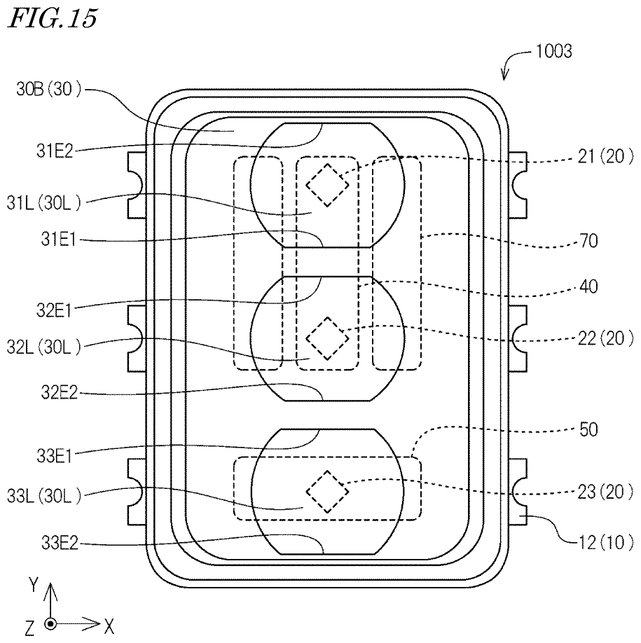

A light-emitting device 1003 of a third embodiment is described with reference to FIGS. 15 to 16. As illustrated in FIGS. 15 and 16, the light-emitting device 1003 of the third embodiment is different from the light-emitting device 1001 of the first embodiment in that the light-transmissive member 30 does not include the first connecting portion and the second connecting portion. The light-emitting device 1003 of the third embodiment has the same configuration as the light-emitting device 1001 of the first embodiment except for the light-transmissive member 30.

As illustrated in FIG. 15, at least a part of a lateral surface of the first lens portion 31L including the first lens first outer edge portion 31E1 is preferably a surface orthogonal to the first direction (Y direction). The first lens first outer edge portion 31E1 is a part of the outer edge of the first lens portion 31L and is located between the first light-emitting element 21 and the second light-emitting element 22 in a top view. This facilitates reduction in size of the light-emitting device 1003 in the first direction (Y direction). Similarly, at least a part of the lateral surface of the second lens portion 32L including the second lens first outer edge portion 32E1 is preferably a surface orthogonal to the first direction (Y direction). The second lens first outer edge portion 32E1 is a part of the outer edge of the second lens portion 32L and is located between the first light-emitting element 21 and the second light-emitting element 22 in a top view. At least a part of the lateral surface of the second lens portion 32L including the second lens second outer edge portion 32E2 is preferably a surface orthogonal to the first direction (Y direction). The second lens second outer edge portion 32E2 is a part of the outer edge of the second lens portion 32L and is located between the second light-emitting element 22 and the third light-emitting element 23 in a top view. At least a part of the lateral surface of the third lens portion 33L including the third lens first outer edge portion 33E1 is preferably a surface orthogonal to the first direction (Y direction). The third lens first outer edge portion 33E1 is a part of the outer edge of the third lens portion 33L and is located between the second light-emitting element 22 and the third light-emitting element 23 in a top view.

Certain embodiments of the present invention have been described above with reference to specific examples. However, the present invention is not limited to these specific examples. All aspects that can be practiced by a person skilled in the art changing the design as appropriate based on the above-described embodiments of the present invention are also included in the scope of the present invention, as long as they encompass the spirit of the present invention. In addition, in the spirit of the present invention, a person skilled in the art can conceive of various modified examples and modifications, and those modified examples and modifications will also fall within the scope of the present invention.

What is claimed is:

1. A light-emitting device comprising:
a support;
a first light-emitting element and a second light-emitting element that are aligned in a first direction and located on the support;
a light-transmissive member including:
a first lens portion overlapping the first light-emitting element in a top view,
a second lens portion overlapping the second light-emitting element in a top view, and
a first connecting portion connecting the first lens portion and the second lens portion; and
a reflective member overlapping the first connecting portion in a top view.

2. The light-emitting device according to claim 1, wherein the reflective member is located around the first light-emitting element and overlaps the first lens portion in a top view.

3. The light-emitting device according to claim 1, wherein the reflective member is located around the second light-emitting element and overlaps the second lens portion in a top view.

4. The light-emitting device according to claim 1, wherein a maximum length of the first connecting portion in a second direction orthogonal to the first direction is longer than a maximum length of the reflective member in the second direction.

5. The light-emitting device according to claim 1, wherein
in a top view, an outer edge of the first lens portion includes:
a first lens first outer edge portion located between the first light-emitting element and the second light-emitting element, and
a first lens second outer edge portion located on a side opposite to the first lens first outer edge portion with respect to a center of the first light-emitting element, and
in a top view, at least a part of the first lens first outer edge portion overlaps the reflective member and at least a part of the first lens second outer edge portion is spaced apart from the reflective member.

6. The light-emitting device according to claim 5, wherein at least a part of a lateral surface of the first lens portion including the first lens second outer edge portion is a surface orthogonal to the first direction.

7. The light-emitting device according to claim 1, wherein
in a top view, an outer edge of the second lens portion includes a second lens first outer edge portion located between the first light-emitting element and the second light-emitting element, and a second lens second outer edge portion located on a side opposite to the second lens first outer edge portion with respect to a center of the second light-emitting element, and
in a top view, at least a part of the second lens first outer edge portion overlaps the reflective member, and at least a part of the second lens second outer edge portion is spaced apart from the reflective member.

8. The light-emitting device according to claim 1, further comprising:
a third light-emitting element located on the support and aligned with the first light-emitting element in the first direction; and
a light absorbing member located around the third light-emitting element, wherein
the light-transmissive member includes a third lens portion overlapping the third light-emitting element and the light absorbing member in a top view, and a second connecting portion connecting the second lens portion and the third lens portion.

9. The light-emitting device according to claim 8, wherein
a light emission peak wavelength of the first light-emitting element is 430 nm or more and less than 480 nm,
a light emission peak wavelength of the second light-emitting element is 500 nm or more and less than 580 nm, and
a light emission peak wavelength of the third light-emitting element is 600 nm or more and less than 780 nm.

10. The light-emitting device according to claim 2, wherein the reflective member is located around the second light-emitting element and overlaps the second lens portion in a top view.

11. The light-emitting device according to claim 2, wherein a maximum length of the first connecting portion in a second direction orthogonal to the first direction is longer than a maximum length of the reflective member in the second direction.

12. The light-emitting device according to claim 2, wherein
in a top view, an outer edge of the first lens portion includes:
a first lens first outer edge portion located between the first light-emitting element and the second light-emitting element, and
a first lens second outer edge portion located on a side opposite to the first lens first outer edge portion with respect to a center of the first light-emitting element, and
in a top view, at least a part of the first lens first outer edge portion overlaps the reflective member and at least a part of the first lens second outer edge portion is spaced apart from the reflective member.

13. The light-emitting device according to claim 12, wherein at least a part of a lateral surface of the first lens portion including the first lens second outer edge portion is a surface orthogonal to the first direction.

14. The light-emitting device according to claim 2, wherein
in a top view, an outer edge of the second lens portion includes a second lens first outer edge portion located between the first light-emitting element and the second light-emitting element, and a second lens second outer edge portion located on a side opposite to the second lens first outer edge portion with respect to a center of the second light-emitting element, and
in a top view, at least a part of the second lens first outer edge portion overlaps the reflective member, and at least a part of the second lens second outer edge portion is spaced apart from the reflective member.

15. The light-emitting device according to claim 2, further comprising:
a third light-emitting element located on the support and aligned with the first light-emitting element in the first direction; and
a light absorbing member located around the third light-emitting element, wherein
the light-transmissive member includes a third lens portion overlapping the third light-emitting element and the light absorbing member in a top view, and a second connecting portion connecting the second lens portion and the third lens portion.

16. The light-emitting device according to claim 15, wherein
a light emission peak wavelength of the first light-emitting element is 430 nm or more and less than 480 nm,
a light emission peak wavelength of the second light-emitting clement is 500 nm or more and less than 580 nm, and
a light emission peak wavelength of the third light-emitting clement is 600 nm or more and less than 780 nm.
